(19) United States
(12) Patent Application Publication
(10) Pub. No.: US 2026/0186093 A1
(43) Pub. Date: Jul. 2, 2026

(54) APPROXIMATION OF LONG-TERM EDDY CURRENTS

(71) Applicant: CANON MEDICAL SYSTEMS CORPORATION, Tochigi (JP)

(72) Inventors: Sebastian ROSENZWEIG, Zürich (CH); Bertram WILM, Stäfa (CH); David BRUNNER, Jona (CH)

(73) Assignee: CANON MEDICAL SYSTEMS CORPORATION, Tochigi (JP)

(21) Appl. No.: 19/433,396

(22) Filed: Dec. 26, 2025

Related U.S. Application Data
(60) Provisional application No. 63/739,322, filed on Dec. 27, 2024.

(51) Int. Cl. G01R 33/561; G01R 33/54

(52) U.S. Cl. CPC G01R 33/5611; G01R 33/543

(57) ABSTRACT

An image reconstruction method in an MRI system includes receiving k-space data acquired by scanning an imaging object using the MRI system with an input gradient applied to a gradient system of the MRI system, and reconstructing an image of the imaging object, based on the received k-space data, the input gradient, and a gradient response model of the gradient system. The gradient response model is determined by: measuring a gradient field generated by the gradient system in response to a probing gradient, constructing the gradient response model of the gradient system, based on a numerical kernel and a plurality of basis functions, using the constructed gradient response model to predict a gradient field generated by the gradient system in response to the probing gradient, and optimizing model parameters of the constructed gradient response model by minimizing an error between the predicted gradient field and the measured gradient field.

### CROSS-REFERENCE TO RELATED APPLICATIONS

The present application claims the benefit of priority to provisional Application No. 63/739,322, filed on Dec. 27, 2024, the entire contents of which are incorporated herein by reference.

### BACKGROUND

### Field

The present disclosure is related to approximating magnetic field responses of gradient switching with long time constants in magnetic resonance imaging (MRI) systems.

### Description of the Related Art

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Magnetic resonance imaging (MRI) involves strong gradients, including diffusion encoding gradients that can induce eddy currents with long decay times of up to several seconds. The eddy currents can affect image acquisition and specifically the k-space trajectory of magnetic resonance data prior to image reconstruction.

### SUMMARY

In one embodiment, the present disclosure is directed to a method for image reconstruction in a magnetic resonance imaging (MRI) system. The method includes: receiving k-space data acquired by scanning an imaging object using the MRI system with an input gradient applied to a gradient system of the MRI system; and reconstructing an image of the imaging object, based on the received k-space data, the input gradient, and a gradient response model of the gradient system. The gradient response model is determined by: measuring a gradient field generated by the gradient system in response to a probing gradient, constructing the gradient response model of the gradient system, based on a numerical kernel and a plurality of basis functions, using the constructed gradient response model to predict a gradient field generated by the gradient system in response to the probing gradient, and optimizing model parameters of the constructed gradient response model by minimizing an error between the predicted gradient field and the measured gradient field. At least some of the plurality of basis functions are each expressed as a sum of a plurality of exponential-type decay functions.

In one embodiment, the present disclosure is related to an apparatus for image reconstruction in an MRI system. The apparatus includes processing circuitry configured to: receive k-space data acquired by scanning an imaging object using the MRI system with an input gradient applied to a gradient system of the MRI system, and reconstruct an image of the imaging object, based on the received k-space data, the input gradient, and a gradient response model of the gradient system. The gradient response model is determined by: measuring a gradient field generated by the gradient system in response to a probing gradient, constructing the gradient response model of the gradient system, based on a numerical kernel and a plurality of basis functions, using the constructed gradient response model to predict a gradient field generated by the gradient system in response to the probing gradient, and optimizing model parameters of the constructed gradient response model by minimizing an error between the predicted gradient field and the measured gradient field. At least some of the plurality of basis functions are each expressed as a sum of a plurality of exponential-type decay functions.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is an illustration of simulated convolution kernels, according to one embodiment of the present disclosure;

FIG. 2 is an illustration of basis functions, according to one embodiment of the present disclosure;

FIG. 3 is an illustration of singular values, according to one embodiment of the present disclosure;

FIG. 4 is a schematic of the composition of a response function, according to one embodiment of the present disclosure;

FIG. 5 is a gradient comparison graph, according to one embodiment of the present disclosure;

FIG. 6 is a reconstructed image, according to one embodiment of the present disclosure;

FIG. 7 is a reconstructed image, according to one embodiment of the present disclosure;

FIG. 8 is a reconstructed image, according to one embodiment of the present disclosure;

FIG. 9 is a reconstructed image, according to one embodiment of the present disclosure;

FIG. 10 is a trajectory phase graph, according to one embodiment of the present disclosure;

FIG. 11 is a trajectory phase difference graph, according to one embodiment of the present disclosure;

FIG. 12 is a trajectory phase graph, according to one embodiment of the present disclosure;

FIG. 13 is a trajectory phase graph, according to one embodiment of the present disclosure;

FIG. 14 is a trajectory phase graph, according to one embodiment of the present disclosure;

FIG. 15 is a trajectory phase graph, according to one embodiment of the present disclosure;

FIG. 16 is a trajectory phase difference graph, according to one embodiment of the present disclosure;

FIG. 17 is a trajectory phase difference graph, according to one embodiment of the present disclosure;

FIG. 18 is a trajectory phase difference graph, according to one embodiment of the present disclosure;

FIG. 19 is a trajectory phase difference graph, according to one embodiment of the present disclosure;

FIG. 20 illustrates a flowchart of an exemplary image reconstruction method in accordance with embodiments of the present disclosure; and

FIG. 21 is a schematic block diagram of a magnetic resonance imaging system, according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For example, the order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

Furthermore, as used herein, the words “a,” “an,” and the like generally carry a meaning of “one or more,” unless stated otherwise.

Magnetic resonance imaging (MRI) involves the generation of switched gradients in the magnetic field during the imaging process in order to determine spatial information from a magnetic resonance (MR) signal. Diffusion MRI (or diffusion-weighted MRI, DW-MRI) further involves application of pulsed diffusion-encoding gradients to sensitize the MRI system to diffusion of water molecules. As an example, the pulsed gradients can be on either side of a radiofrequency (RF) pulse and can include a pulsed gradient that is applied immediately prior to image acquisition. Each pulsed gradient can result in eddy currents (electrical currents) or other transient responses, which can have decay times ranging from sub-milliseconds (ms) to several seconds. The eddy currents in turn generate a secondary magnetic field superimposing the gradient pulse. The eddy currents can be present during image acquisition and can affect how the MR data is acquired and processed. Specifically, the eddy currents can distort the measurement of gradients such that the actual gradient waveform includes a superposition of eddy currents and the encoding gradients that are generated by an MRI system. The deviation in spatial-temporal field evolution can affect how an MR signal is mapped to k-space (the trajectory to k-space) and how signal and contrast is generated. The resulting image will thus include artifacts unless the deviations caused by the eddy currents can be characterized and accounted for in the image reconstruction or post-processing process.

In one embodiment, the present disclosure is directed to approximation and modeling of eddy currents, including their long-term behavior, without requiring actual (experimental) measurement of an MRI system's response over the full decay period of an eddy current. Typical techniques for determining the effects of eddy currents involve monitoring a system's magnetic field in order to determine k-space positions of data or acquiring a system response (e.g. an output gradient waveform) to certain probing gradients. Each of these techniques can require specific equipment, such as a phantom or a field camera for measuring magnetic fields, and can be limited by the amount (duration or frequency) of sensor or scanner data that can be collected from a system.

A system response to input gradients can be characterized by a Gradient Impulse Response Function (GIRF) h(t), which models the relationship between an input gradient waveform and an output gradient; or a Gradient Transfer Function H(w), a Fourier representation of a GIRF. The GIRF can be experimentally determined by playing gradient waveforms (probing gradients) having shapes i(t) and measuring an output response of an actual gradient waveform o(t) that is played out from the gradient system (coils). The output waveform o(t) can then be modeled as o(t)=i(t)*h(t) or O(ω)=I(ω)×H(ω) based on impulse response measurements, wherein * denotes a convolution function. However, conventional techniques for probing a system are not sufficiently sensitive and accurate to long-term eddy currents, which decay over time, and require measurement of output data that is difficult to acquire. For example, a blip sequence of input gradients is ineffective to probe eddy currents with longer time constants because the slopes are close in time such that their eddy currents of opposite signs overlap and are canceled out. The term “gradient field” or “gradient” can be generally understood as spatial field distribution(s) of the magnetic field. The gradient can be any spatial field pattern into which a spatial-temporal field pattern is decomposed. In particular, field distributions can be patterns of spherical or cylindrical harmonic functions. The input and output spatial field patterns of a response function do not have to be the same, but the same approach can be applied to characterization and prediction for cross-terms, which can be gradient fields in different directions or having different shapes from an input gradient. For example, a gradient field can excite a uniform or linear dynamic field or more complex field patterns that may be described by higher polynomial order. The presented methods can be used to characterize a set of output field distributions from each driven input field distribution, e.g. a distribution along a gradient axis or from an active shim coil. In this manner, the methods presented herein can be used for any gradient responses including non-linear spatial patterns.

An approach to measurement can involve representing eddy currents with ramp-down sequences comprising a train of strong trapezoidal gradients with rising and falling ramps that are sufficiently far apart to prevent the signals from canceling each other out. However, these strong trapezoidal gradients de-phase field probes or NMR coherence in phantoms, which leads to signal drop-out during the gradient and incomplete measurement of an output response. Furthermore, GIRFs should model a response over multiple seconds in order to fully resolve decaying eddy currents. The length of the GIRF can require a large number of samples (e.g. approximately 10⁶ samples at a temporal resolution of 4 microseconds (us)), which results in large degrees of freedom. Typical measurements only span for less than 100 ms, e.g. about 40 ms or 10⁴ samples, resulting in limited frequency resolution and a highly underdetermined system of equations to be solved for a GIRF.

In one embodiment, the present disclosure is directed to modeling a long-term response of a gradient system using a representation of exponential decay that can be easily optimized based on a limited amount of experimentally acquired data. In one embodiment, a GIRF kernel h(τ) can be modeled by Equation 1:

$$h ( τ , {β}_{1} , … , {β}_{{N}_{b}} ) = {h}_{0} ( τ ) + {\sum }_{i = 1}^{{N}_{b}} {β}_{i} {u}_{i} \qquad Equation 1$$

Wherein τ is time, βᵢ are weighting coefficients, and uᵢ are temporal basis functions representing a weighted sum of exponential functions to model a decay response of an eddy current. The initial short-term response of the eddy current can be characterized by the numerical function h₀(τ). The function can be optimized by determining the initial function h₀(τ) and the weighting coefficients based on measured output gradient waveforms. As an example, h₀(τ) can contain an array of discrete form exponentials modeling an oscillation. Separating the h₀(τ) term from the basis functions can capture the more complex initial response separately from the long-term behavior. In one embodiment, the initial term h₀(τ) can include long-term behaviors of the GIRF. In one embodiment, the later terms

$${\sum }_{i = 1}^{{N}_{b}} {β}_{i} {u}_{i}$$

can include short-term behaviors of the GIRF. Thus, the use of “short-term” and “long-term” are not necessarily exclusive descriptions of the terms.

In MRI systems, an input gradient waveform and the corresponding measured gradient field response can exhibit a timing offset, referred to as a gradient delay. In one embodiment, the gradient response model can include the gradient delay as an additional term, e.g., a delay parameter. The gradient delay can be removed or compensated prior to processing, or can be fitted jointly with other model parameters during optimization.

Accordingly, the “input gradient” as used herein can be any gradient waveform applied to the gradient system. In one embodiment, the input gradient can be pre-processed prior to use, for example, to compensate for the gradient delay described above. Additionally or alternatively, the input gradient can be pre-processed to compensate for gradient nonlinearities (e.g., amplitude nonlinearity). One skilled in the art will appreciate that other pre-processing can also be applied to the input gradient, and that the foregoing examples are merely illustrative rather than limiting.

A gradient G^{EC}(t) that is induced by an eddy current (EC) can be modeled as

$${G}^{E C} ( t ) \approx - \frac{d}{dt} G ( t ) * E ( t ) , wherein \frac{d}{dt} G ( t )$$

is the derivative of a gradient waveform G(t) and the eddy current impulse response E(t) can be modeled as a sum of exponential decay functions after the eddy current is induced (t>0),

$$E ( t ) = \{ \begin{matrix}{\sum }_{n = 1}^{N} {α}_{n} {e}^{- t / {σ}_{n}} & t \geq 0 \\ 0 & t < 0\end{matrix}$$

wherein each αₙ is an initial response and each σₙ is an (potentially complex valued) exponential decay constant.

A derivative of a one-dimensional signal can be approximated as a convolution of the signal with a kernel K=[−1, 1] such that G^{EC}(t)≈−(G(t)*K)*E(t), which is equivalent to −G(t)*(K*E(t)). It can be appreciated that the kernel K=[−1, 1] can vary. The resulting gradient Gᵣₑₛ can therefore be represented by Gᵣₑₛ=G(t)+G^{EC}(t)≈G(t)*(δ(t)−(K*E(t))): G(t)*E(t) wherein

$$ℰ ( t ) := \{ \begin{matrix}δ ( t ) - {\sum }_{n = 1}^{N} {\sum }_{m = 1}^{M} K * {α}_{n} {e}^{- \frac{t}{{σ}_{m}}} , t \geq 0 \\ 0 , t < 0\end{matrix}$$

The number of exponentials N, M that are needed to resolve the function ε(t) are unknown. In one embodiment, the summations can be approximated using basis functions to provide a compact and accurate representation of the gradient induced by the eddy current.

In one embodiment, the basis u(t) functions that are used to approximate the sum can be determined by simulating convolution kernels ε(t). As an example, a few thousand convolution kernels can be simulated such that N×M=10000. In one example, the convolution kernels can be simulated across a range of parameters a, =[0.1:1:10] and σₘ=[10⁻⁴:5×10⁻³:5] seconds. The range of parameters can be larger or smaller than the example given and/or can include smaller or larger step sizes.

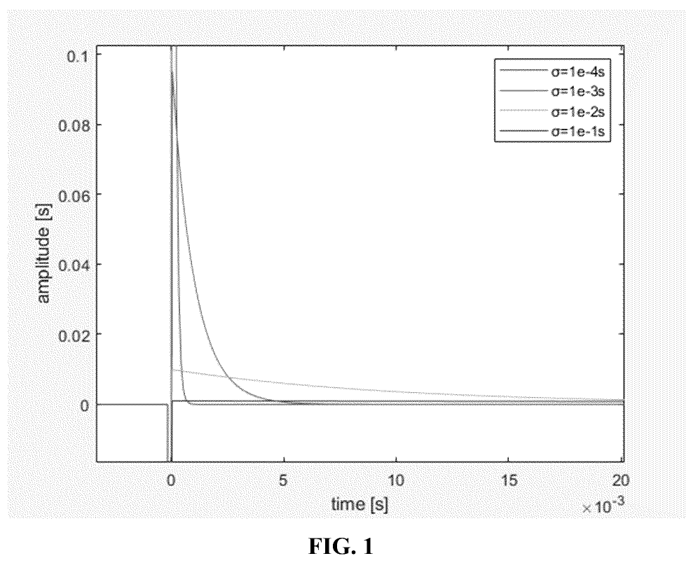

FIG. 1 is an illustration of simulated convolution kernels to mimic an exponential decay with amplitude α=1 for different decay times σ=10⁻⁴, 10⁻³, 10⁻², 10⁻¹ seconds.

In one embodiment, the simulated convolution kernels can be stacked in a matrix:

$$D = \{ \begin{matrix}{α}_{1} {e}^{- t / {σ}_{1}} \\ {α}_{1} {e}^{- t / {σ}_{2}} \\ … \\ {α}_{2} {e}^{- t / {σ}_{1}} \\ … \\ {α}_{N} {e}^{- t / {σ}_{M}}\end{matrix}$$

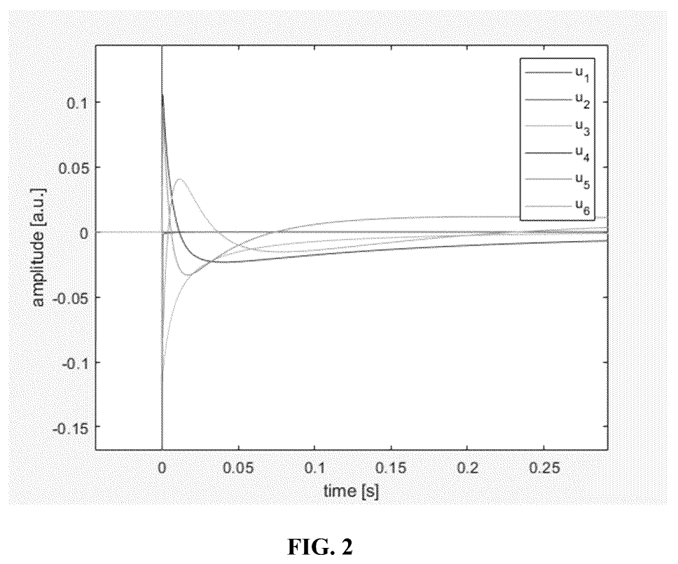

The principal components of the matrix can be determined using singular value decomposition (SVD). SVD can factor the matrix D having dimensions P×Q into three matrices, D=USV^{H}, wherein Uis a P×P unitary matrix, S is an P×Q diagonal matrix, and V^{H} is an Q×Q matrix. The values of U, S, and V^{H} can be determined based on the singular values and eigenvectors/eigenvalues of D and its transpose. The SVD matrices can then be used for principal component analysis to determine the principal components. FIG. 2 is an illustration of basis functions (singular vectors) u₁-u₆ determined from SVD of the matrix D. The initial six basis functions can be the most relevant basis functions based on the leading eigenvectors of the decomposition matrix U.

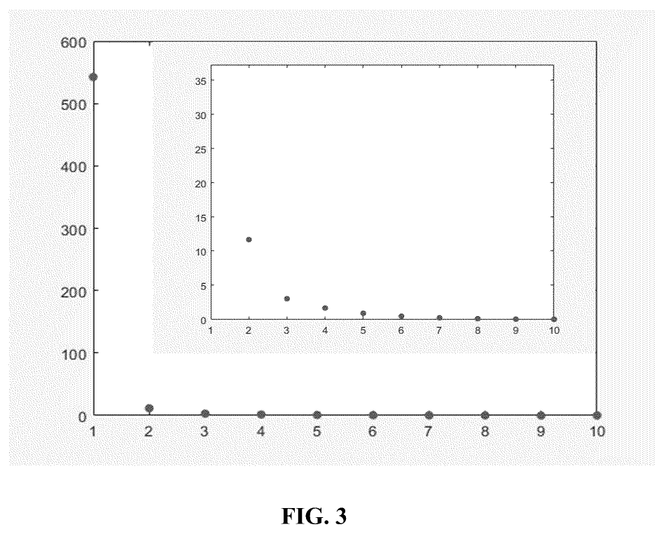

FIG. 3 is an illustration of singular values corresponding to the first 10 basis functions. The values of FIG. 3 show that only the first few components carry significant information. In one embodiment, the simulated decays can be represented with high accuracy by N_{b}=5 basis functions. In one embodiment, N_{b} can be around 5 or greater than 5 or less than 5.

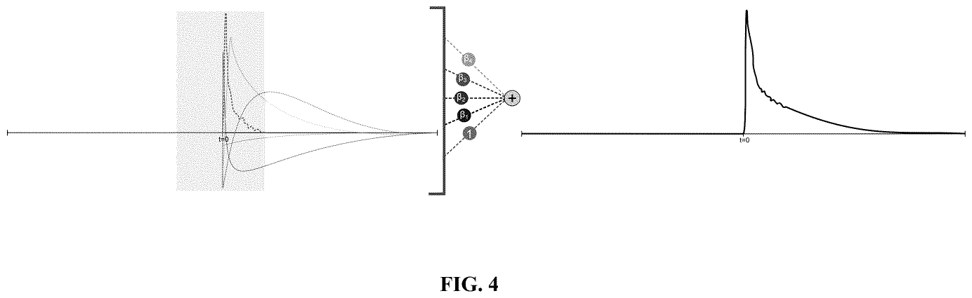

In one embodiment, some of the long-term term eddy currents can therefore be represented by a linear combination

$${\sum }_{i = 1}^{{N}_{b}} {β}_{i} {u}_{i} \qquad ( Equation 1 )$$

wherein uᵢ are the basis functions and N_{b}=5. FIG. 4 is a schematic of the composition of the GIRF of Equation 1. Several long-term basis functions uᵢ can be weighted by weighting coefficients βᵢ and superimposed with a numeric contribution in h₀ of limited size substantially representing the short-term response. The GIRF can be close to zero for t<0 due to causality and the convolution. In one embodiment, the number of samples of h₀(τ) can provide numerical freedom and can be adapted for complex short-term behavior.

The left graph illustrates the individual components of the GIRF, including the short-term response h₀(τ) and a limited number of basis functions uᵢ. The basis functions uᵢ can be weighted and added to the short-term response to generate the response characterized by the GIRF and illustrated in the right graph. In one embodiment, the weighting coefficients βᵢ can be determined using an optimization step. In one embodiment, the short-term kernel h₀ can be determined in the same optimization step or a separate optimization step. In one embodiment, the short-term kernel can correspond to approximately 40 ms to 100 ms. The remainder of the response (approximately 1-2 seconds, up to approximately 5 seconds, or more than 5 seconds) can be characterized by the basis functions of multi-exponential decays.

In one embodiment, parameters of the GIRF can be optimized using training data. The training data can be acquired by measuring a system response to inputs that include the aforementioned ramp-down sequences to switch off between strong gradients. The system response can include responses to induced eddy currents of linear or of higher spatial orders. In one embodiment, the measurement can be performed using field monitoring or a phantom experiment. An input gradient x_{Gnom} can be input to the system, and the actual gradient waveforms that are output in response to the input gradient can be measured as field y_{g}.

In one embodiment, the optimization step can include a least-squares optimization to find a function h₀ and coefficients βi to best match the acquired data y_{G} for all performed (and potentially temporally delayed, i.e. piecewise acquired) measurements

$${arg min}_{{h}_{0} , {β}_{i}} {\sum }_{all delays} {‖ {y}_{G}^{d e l a y} - {p}^{d e l a y} ( {x}_{G n o m} * h ( {h}_{0} , {β}_{i} ) ) ‖}^{2}$$

Wherein the actual gradient field y_{g} can be compared with a predicted (simulated) gradient field x_{Gnom}*h that is calculated using the GIRF h and the input gradient x_{Gnom}. The input gradient can be a nominal input gradient. In one embodiment, a delay (or delays) can be applied to the measurement of y_{g} in order to capture the long-term response of the system. The measurement of the gradient field y_{g} can be limited to a range of approximately 40 to 70 ms due to the monitoring probes. Therefore, instead of measuring a full gradient field y_{g} of a long term response, a number of measurements can be made to determine gradient fields

$${y}_{G}^{d e l a y}$$

at varying (delayed) measurement start times. In one embodiment, the delay can range from approximately 1 second to approximately 1 minute or more. The gradients

$${y}_{G}^{d e l a y}$$

can be higher order gradients at certain delays (e.g. 1 ms, 50 ms). In one embodiment, a pattern mask p^{delay} can be applied to the predicted gradient field. The pattern mask (or function) can sample points from the predicted gradient field that match the measured points in the actual gradient field y_{g} for each delay. The pattern mask can crop the convolution of x_{Gnom}*h to the measured range of y_{g} based on the delays applied to measure y_{g}. The second term p^{delay} (x_{Gnom}*h) of Equation 2 can therefore correspond to the measured gradient field y_{g} for proper comparison and optimization. In one embodiment, the optimization can be performed in k-space by integrating the simulated gradient and the measured gradient, respectively.

Equation 2 can be solved to determine the values of β₁, . . . β_{f}N, and the array h₀(τ) for the GIRF h. In one embodiment, the function h=h_{axis→field} can describe the short and long term response of one axis onto one field (zero-order, linear, higher-order) of the gradient system. In one embodiment, the optimization can be performed individually for all combinations of axes and fields (y_{g,x}, y_{g,y}, y_{g,z}, etc.). Since an output can be expanded into a 3^{rd} order spherical harmonic basis with 16 basis functions, 3×16 GTFs can be calculated to capture the effect of gradients on the three physical axes and onto the 16 spherical harmonic fields as detailed in Vannesjo et al. (Magnetic Resonance in Medicine 69:583-593 (2013)

The present disclosure for determining an extended GIRF (or GTF) presents advantages over the conventional GTF approach. For example, the exact number of unknowns, (e.g. the number of decay terms) to represent long-term eddy-currents does not have to be determined. The unstable nonlinear fitting process of a sum of exponentials is circumvented by utilizing a compact basis representation of the exponential decay of the long-term eddy-currents, which allows for a linear fit. Furthermore, the present approach is applicable to scenarios where the full output gradient waveform potentially cannot be measured, such as e.g. ramp-down measurements of strong gradients. In such scenarios, the conventional approach used for blipped input gradients cannot readily be applied, as it usually requires the full output gradient waveform to be available. The present approach also overcomes the problem of underdetermination due to limited measurement duration by constraining the long-term eddy-currents to an exponential decay model. Additionally, the present approach enables the straightforward incorporation of additional complementary measurements of arbitrary length (such as spirals, fast-MRI techniques such as echo-planar imaging, . . . ) to fit the GIRF. In this manner, any waveform can be used to probe the system during the optimization step.

In one embodiment, the method can include pre-emphasis filtering to reduce noise. In one embodiment, the long-term response can be modeled by a linear fit instead of nonlinear multi-exponential fit. In one embodiment, the simulation of the convolutional kernels can include oscillatory terms in addition to (or in place of) exponentials.

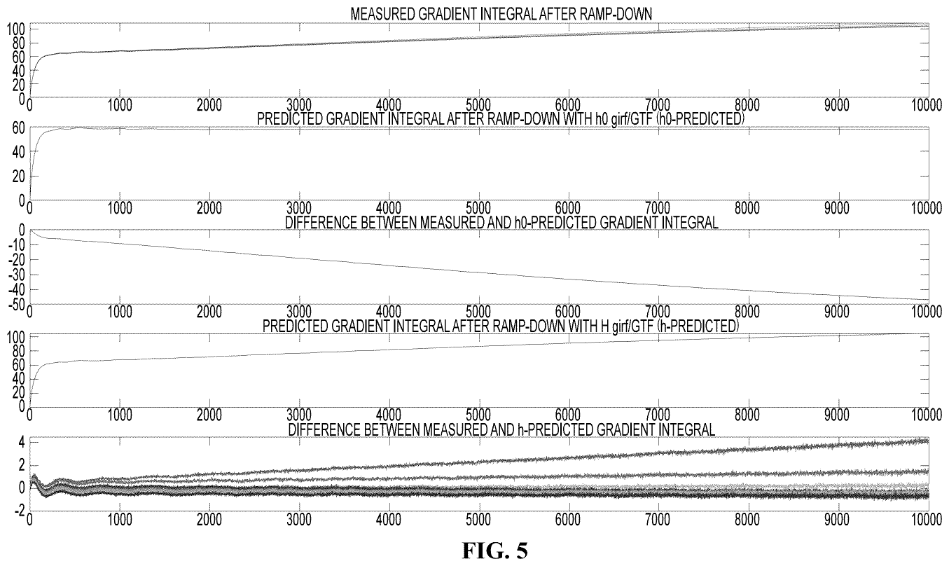

FIG. 5 illustrates predicted gradients using different GIRFs after the ramp-down sequences. The first graph is a measured gradient integral after ramp-down; the second graph is a predicted gradient integral with a GIRF that only includes an h₀ term; the third graph is a difference between the measured gradient integral and the predicted gradient integral; the fourth graph is a predicted gradient integral with a GIRF that includes h₀ and the linear combination

$${\sum }_{i = 1}^{{N}_{b}} {β}_{i} {u}_{i}$$

as in Equation 1; and the fifth graph illustrates differences between measured and predicted gradient integrals for the GIRF of Equation 1.

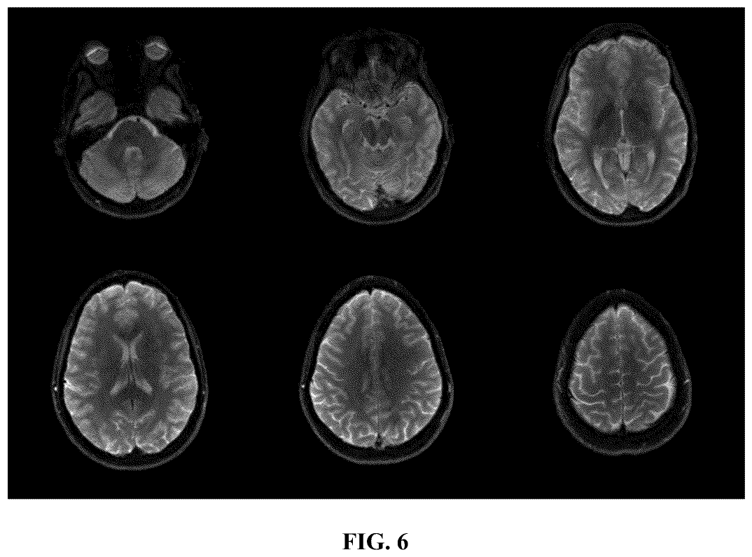

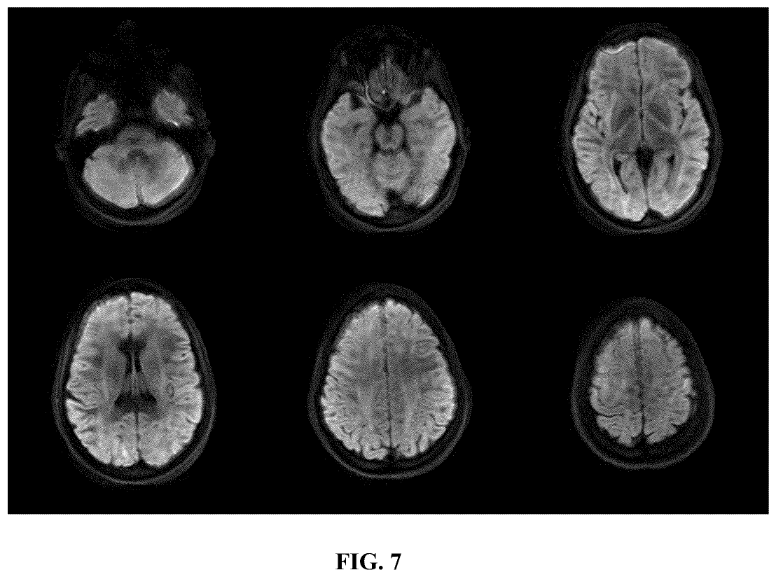

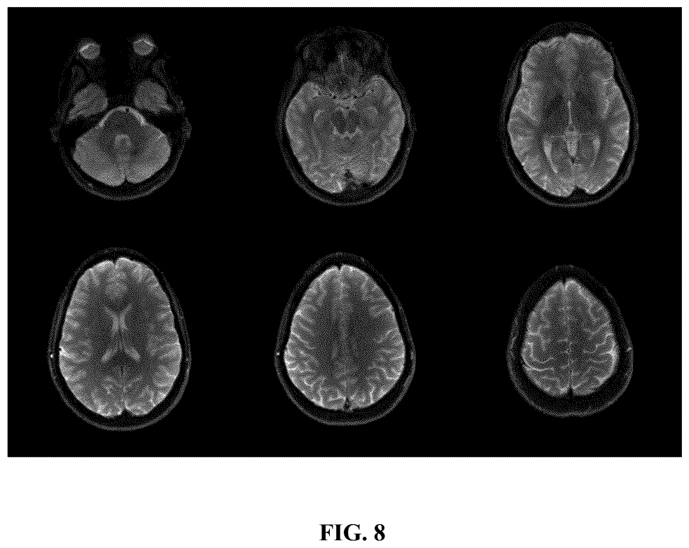

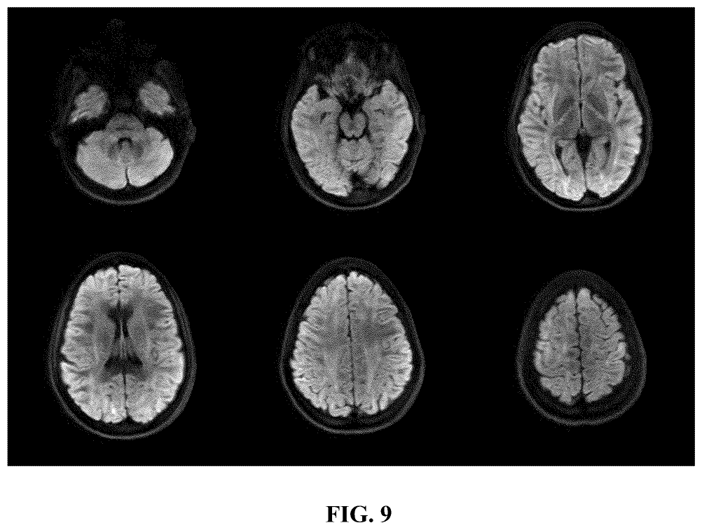

FIGS. 6 and 7 include examples of spiral image reconstruction using a conventional GIRF consisting of a numerical kernel calculated from a blip sequence. Compared to the field monitored reference images (not shown) the reconstructed images show slight intensity variations, some blurriness (especially in the DW scan (FIG. 7)), and a slight field of view change. These effects are much reduced for the images (FIGS. 8 and 9) reconstructed using a GIRF that consist of a numerical kernel and the additional basis (Eq. 1) calculated from blip and ramp-down data. In the GIRF calibration measurement sequence, the blip-sequence is not sensitive to long-term eddy currents as the fast succession of the rising and falling ramps of the blips lead to long-term eddy current cancelation. In one embodiment, the measurement sequence can include field-monitoring of ko.

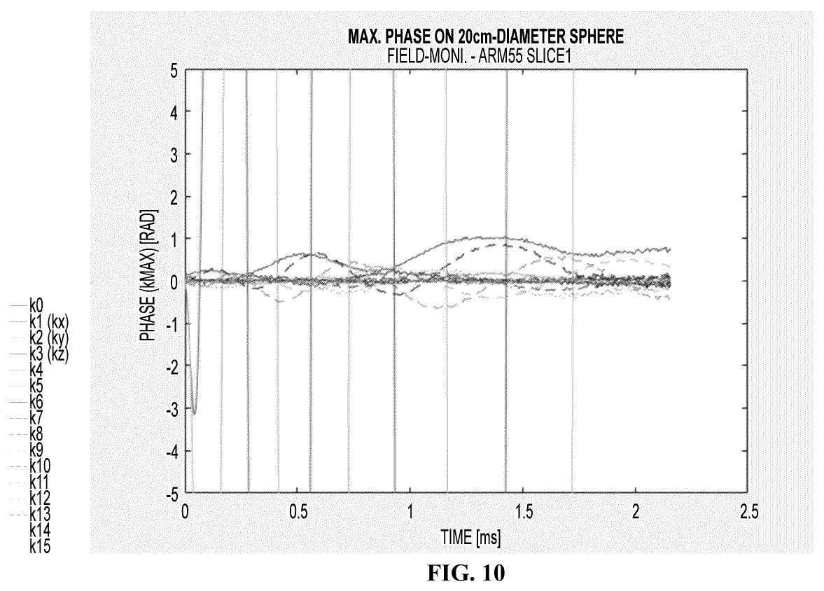

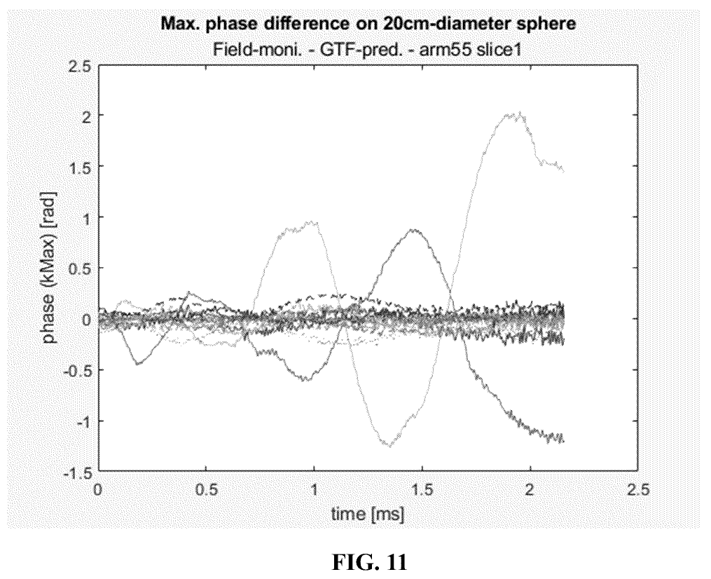

FIG. 10 illustrates the maximum phase on a sphere with a 20 cm diameter for field-monitoring trajectory. FIG. 11 illustrates the maximum phase difference on a sphere with a 20 cm diameter for field-monitoring trajectory and GTF-predicted trajectory.

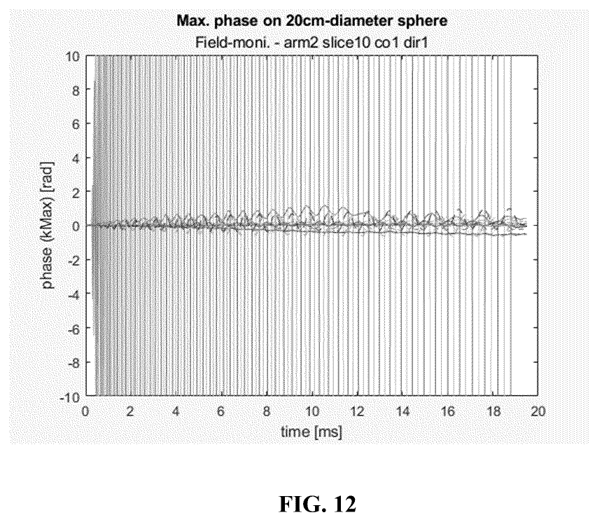

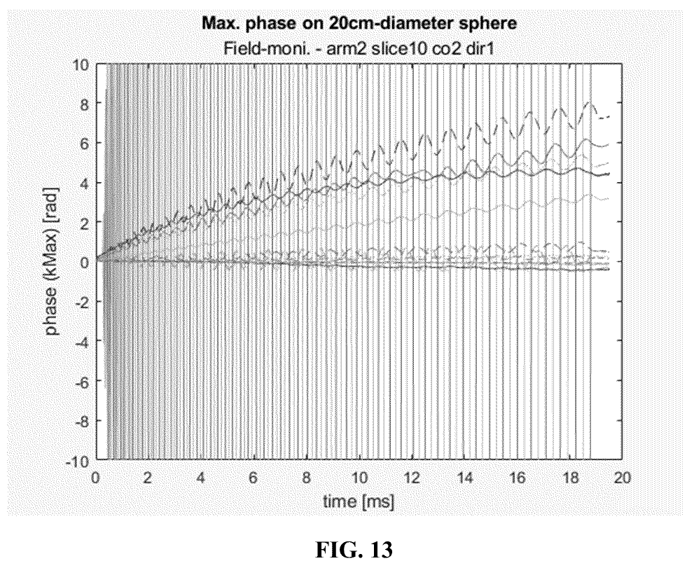

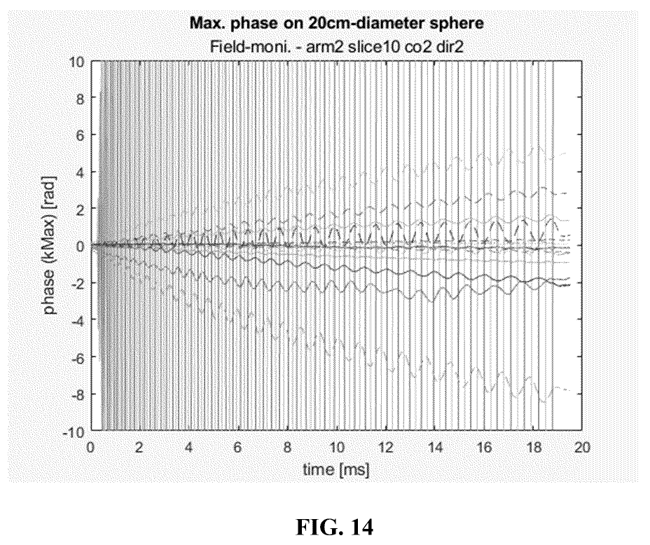

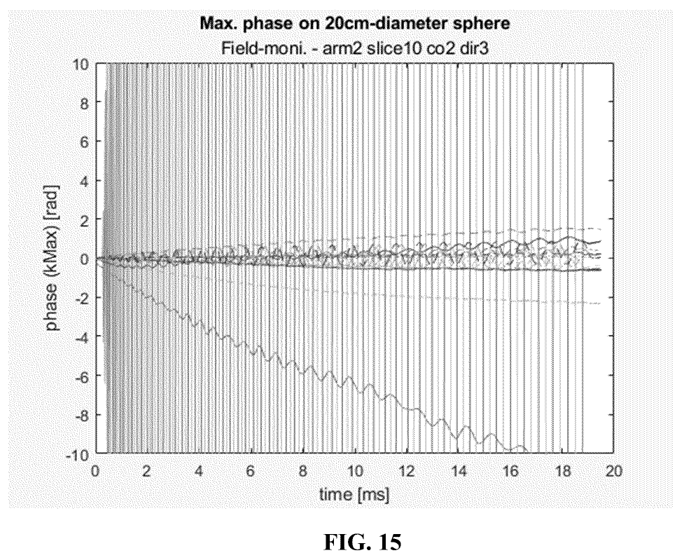

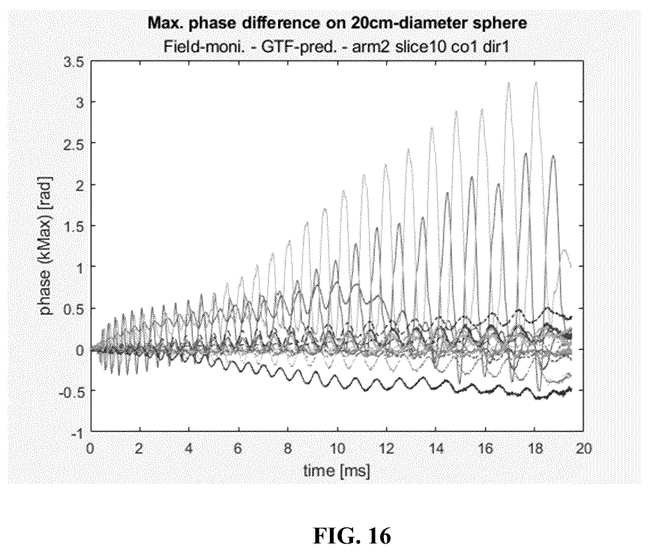

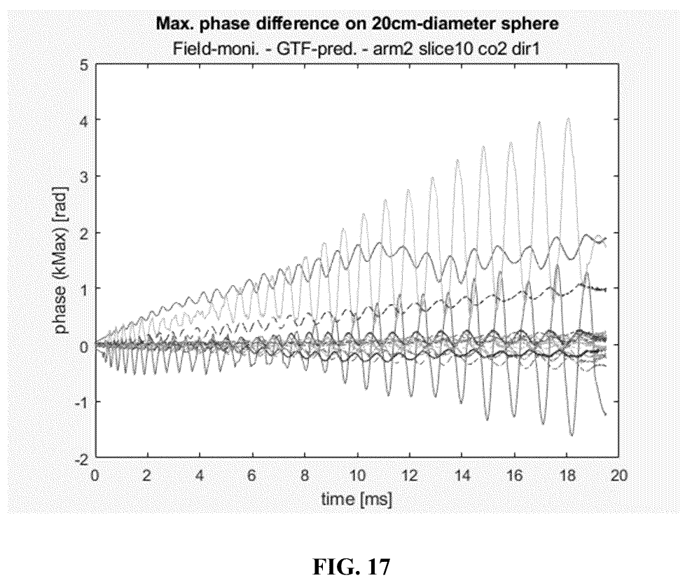

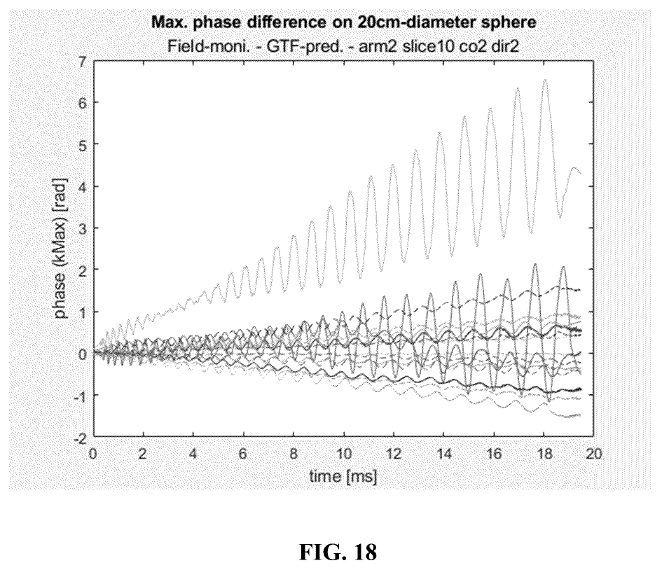

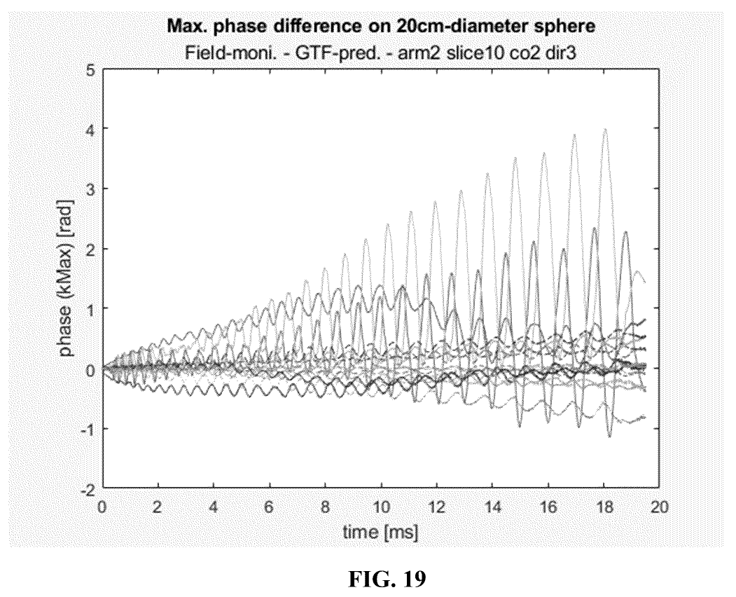

FIG. 12 illustrates the maximum phase on a sphere with 20 cm diameter for non-DW images for field monitoring trajectory. FIG. 13-FIG. 15 illustrate the maximum phase on a sphere with 20 cm diameter for DW images for field monitoring trajectory. FIGS. 16-19 illustrate the maximum phase difference on a sphere with 20 cm diameter between field-monitoring trajectory and GTF-predicted trajectory. Drift during calibration or non-linearity of hardware may be sources of error in the trajectory, which may be corrected for.

In one embodiment, the GIRF can include basis functions to describe a short-term eddy current response. A GTF using basis functions can be used in gradient response harvesting as described in 2020 March; 39(3): 806-815. doi: 10.1109/TMI.2019.2936107. Epub 2019 Aug. 19. Gradient Response Harvesting for Continuous System Characterization During MR Sequences. Bertram J Wilm, Benjamin E Dietrich, Jonas Reber, S Johanna Vannesjo, Klaas P Pruessmann, which is incorporated herein by reference in its entirety. For example, time-varying parts of the GTF can be fitted to the basis functions. In one embodiment, a set of exponential basis functions can be calculated from a set of compressed basis functions u for the GIRF response for faster fitting of the exponentials or more robust fitting for ECC (eddy current correction by pre-emphasis).

In the above descriptions, the gradient response model and the basis functions have been illustrated using exponential decay functions as an example. However, one skilled in the art will appreciate that the disclosed concepts are not limited to using strictly exponential functions to construct the basis functions and the gradient response model. In various implementations, one or more of the decay functions used to construct the basis functions can be exponential-type decay functions that, over a desired time interval, exhibit a decay behavior substantially similar to that of an exponential function.

For example, such exponential-type decay functions can include power-law decay functions. Other functional forms are also practicable, provided that their magnitude decreases over time in a manner comparable to a “pure” exponential decay function. For instance, Padé-type decay functions can be selected to approximate an exponential decay over a desired time range. Accordingly, although the terms “exponentials,” “exponential decays,” “exponential functions” are used throughout the present disclosure for clarity, it is intended to encompass both strictly exponential decay functions and such substantially exponential or exponential-type decay functions that implement the modeling concepts provided in the disclosure.

In the above examples, the probing gradient has been described as including a sequence of trapezoidal nominal gradients. However, one skilled in the art will appreciate that the disclosed concepts are not limited to trapezoidal waveforms. In other embodiments, the probing gradient can be implemented as a spiral gradient waveform, for example, provided that it supplies useful information on the gradient response of the system. Accordingly, the trapezoidal nominal gradients are merely illustrative, and do not exclude other suitable probing gradient waveforms.

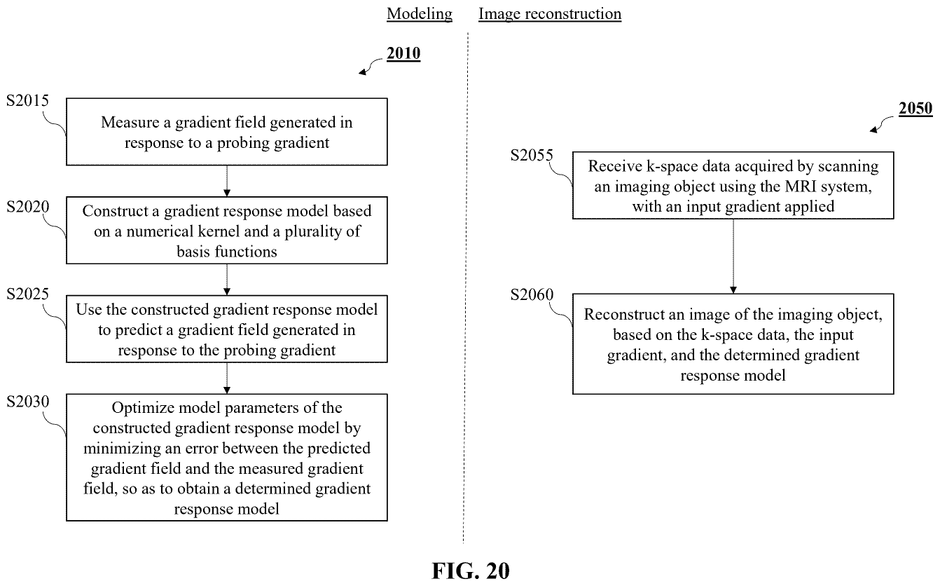

FIG. 20 illustrates a flowchart of an exemplary image reconstruction method in accordance with embodiments of the present disclosure. The method includes two stages, a modeling stage 2010 and an image reconstruction stage 2050.

During the modeling stage 2010, a gradient response model of the MRI gradient system is determined. In step S2015, a gradient field generated by the MRI gradient system in response to a probing gradient is measured. In step S2020, a gradient response model is constructed based on a numerical kernel and a plurality of basis functions. In step S2025, the constructed gradient response model is used to predict a gradient field generated by the MRI gradient system in response to the probing gradient. In step S2030, model parameters of the gradient response model are optimized by minimizing an error between the predicted gradient field and the measured gradient field, so as to obtain a determined gradient response model.

During the image reconstruction stage 2050, the determined gradient response model can be used in image reconstruction for clinical or diagnostic scanning. In step S2055, k-space of an imaging object is received. The k-space data can be acquired by scanning the imaging object using the MRI system, with an input gradient applied. In step S2060, an image of the imaging object is reconstructed based on the k-space data, the input gradient, and the gradient response model determined in the modeling stage. In this manner, image quality can be improved by mitigating artifacts caused by eddy currents, for example.

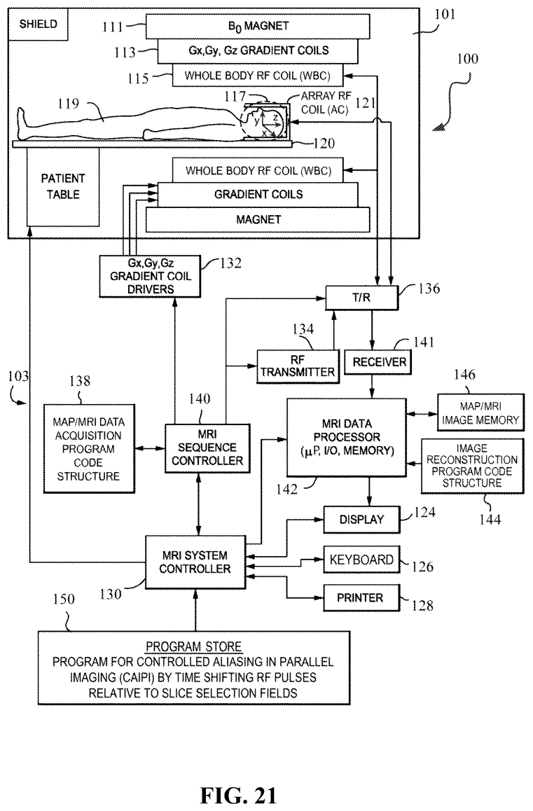

Referring now to FIG. 21, a non-limiting example of a magnetic resonance imaging (MRI) system 100 is shown. The MRI system 100 depicted in FIG. 21 includes a gantry 101 (shown in a schematic cross-section) and various related system components 103 interfaced therewith. At least the gantry 101 is typically located in a shielded room. The MRI system geometry depicted in FIG. 21 includes a substantially coaxial cylindrical arrangement of the static field B0 magnet 111, a Gx, Gy, and Gz gradient coil set 113, and a large whole-body RF coil (WBC) assembly 115. Along a horizontal axis of this cylindrical array of elements is an imaging volume 117 shown as substantially encompassing the head of a patient 119 supported by a patient table 120.

One or more smaller array RF coils 121 can be more closely coupled to the patient's head (referred to herein, for example, as “imaging object” or “object”) in imaging volume 117. As those in the art will appreciate, compared to the WBC (whole-body coil), relatively small coils and/or arrays, such as surface coils or the like, are often customized for particular body parts (e.g., arms, shoulders, elbows, wrists, knees, legs, chest, spine, etc.). Such smaller RF coils are referred to herein as array coils (AC) or phased-array coils (PAC). These can include at least one coil configured to transmit RF signals into the imaging volume, and a plurality of receiver coils configured to receive RF signals from an object, such as the patient's head, in the imaging volume.

The MRI system 100 includes an MRI system controller 130 that has input/output ports connected to a display 124, a keyboard 126, and a printer 128. As will be appreciated, the display 124 can be of the touch-screen variety so that it provides control inputs as well. A mouse or other I/O device(s) can also be provided.

The MRI system controller 130 interfaces with an MRI sequence controller 140, which, in turn, controls the Gx, Gy, and Gz gradient coil drivers 132, as well as the RF transmitter 134, and the transmit/receive switch 136 (if the same RF coil is used for both transmission and reception). The RF transmitter 134 may be composed of two or more transmitter channels for driving two or more RF transmit coils or ports on coils, as is used for RF shimming. The MRI sequence controller 140 includes suitable program code structure 138 for implementing MRI imaging (also known as nuclear magnetic resonance, or NMR, imaging) techniques including B1 field shimming. MRI sequence controller 140 can be configured for MR imaging with or without parallel imaging. Moreover, the MRI sequence controller 140 can facilitate one or more preparation scan (pre-scan) sequences, and a scan sequence to obtain a main scan magnetic resonance (MR) image (referred to as a diagnostic image). MR data from pre-scans can be used, for example, to determine shimming parameters for RF coils 115 and/or 121.

The MRI system components 103 include an RF receiver 141 providing input to data processor 142 so as to create processed image data, which is sent to display 124. The MRI data processor 142 is also configured to access previously generated MR data, images, navigator data, system configuration parameters 146, and/or program code structures 144 and 150.

In one embodiment, the MRI data processor 142 includes processing circuitry. The processing circuitry can include devices such as an application-specific integrated circuit (ASIC), configurable logic devices (e.g., simple programmable logic devices (SPLDs), complex programmable logic devices (CPLDs), and field programmable gate arrays (FPGAs), and other circuit components that are arranged to perform the functions recited in the present disclosure, such as described with respect to FIGS. 1-19.

The processor 142 executes one or more sequences of one or more instructions contained in the program code structures 144 and 150. Alternatively, the instructions can be read from another computer-readable medium, such as a hard disk or a removable media drive. One or more processors in a multi-processing arrangement can also be employed to execute the sequences of instructions contained in the program code structures 144 and 150. In alternative embodiments, hard-wired circuitry can be used in place of or in combination with software instructions. Thus, the disclosed embodiments are not limited to any specific combination of hardware circuitry and software. For example, the program code structure 150 can store instructions that when executed perform the methods described herein.

Additionally, the term “computer-readable medium” as used herein refers to any non-transitory medium that participates in providing instructions to the processor 142 for execution. A computer readable medium can take many forms, including but not limited to, non-volatile media or volatile media. Non-volatile media includes, for example, optical, magnetic disks, and magneto-optical disks, or a removable media drive. Volatile media includes dynamic memory.

Also illustrated in FIG. 21 is a generalized depiction of an MRI system program storage (memory) 150, where stored program code structures such as instructions to perform the method 200 are stored in non-transitory computer-readable storage media accessible to the various data processing components of the MRI system 100. As those in the art will appreciate, the program store 150 can be segmented and directly connected, at least in part, to different ones of the system 103 processing computers having most immediate need for such stored program code structures in their normal operation (i.e., rather than being commonly stored and connected directly to the MRI system controller 130).

Additionally, the MRI system 100 as depicted in FIG. 21 can be utilized to practice exemplary embodiments described herein. The system components can be divided into different logical collections of “boxes” and typically comprise numerous digital signal processors (DSP), microprocessors and special purpose processing circuits (e.g., for fast A/D conversions, fast Fourier transforming, array processing, etc.). Each of those processors is typically a clocked “state machine” wherein the physical data processing circuits progress from one physical state to another upon the occurrence of each clock cycle (or predetermined number of clock cycles).

Furthermore, not only does the physical state of the processing circuits (e.g., CPUs, registers, buffers, arithmetic units, etc.) progressively change from one clock cycle to another during the course of operation, the physical state of associated data storage media (e.g., bit storage sites in magnetic storage media) is transformed from one state to another during operation of such a system. For example, at the conclusion of an image reconstruction process and/or sometimes an image reconstruction map (e.g., coil sensitivity map, unfolding map, ghosting map, a distortion map etc.) generation process, an array of computer-readable accessible data value storage sites in physical storage media will be transformed from some prior state to a new state wherein the physical states at the physical sites of such an array vary between minimum and maximum values to represent real world physical events and conditions. As those in the art will appreciate, such arrays of stored data values represent and also constitute a physical structure, as does a particular structure of computer control program codes that, when sequentially loaded into instruction registers and executed by one or more CPUs of the MRI system 100, causes a particular sequence of operational states to occur and be transitioned through within the MRI system 100.

Numerous modifications and variations of the present invention are possible in light of the above teachings. It is therefore to be understood that within the scope of the appended claims, the invention may be practiced otherwise than as specifically described herein.

1. A method for image reconstruction in a magnetic resonance imaging (MRI) system, the method comprising:
receiving k-space data acquired by scanning an imaging object using the MRI system with an input gradient applied to a gradient system of the MRI system; and
reconstructing an image of the imaging object, based on the received k-space data, the input gradient, and a gradient response model of the gradient system,
wherein the gradient response model is determined by:
measuring a gradient field generated by the gradient system in response to a probing gradient,
constructing the gradient response model of the gradient system, based on a numerical kernel and a plurality of basis functions, wherein at least some of the plurality of basis functions are each expressed as a sum of a plurality of exponential-type decay functions,
using the constructed gradient response model to predict a gradient field generated by the gradient system in response to the probing gradient, and
optimizing model parameters of the constructed gradient response model by minimizing an error between the predicted gradient field and the measured gradient field.

2. The method of claim 1, wherein the measured gradient field is measured with delayed measurement start times.

3. The method of claim 1, wherein the probing gradient includes a sequence of trapezoidal nominal gradients.

4. The method of claim 1, wherein the minimizing of the error between the predicted gradient field and the measured gradient field includes applying a pattern mask to the predicted gradient field.

5. The method of claim 1, wherein the constructed gradient response model is a sum of the numerical kernel and a weighted sum of the plurality of basis functions.

6. The method of claim 5, wherein the optimizing of the model parameters of the constructed gradient response model includes optimizing the numerical kernel and a plurality of weights, each weight of the plurality of weights corresponding to one basis function of the plurality of basis functions.

7. The method of claim 6, wherein the optimizing of the numerical kernel and the plurality of weights is performed in k-space.

8. The method of claim 1, wherein a weighted sum of the plurality of basis functions covers a range of eddy current decay time constants of the gradient system.

9. The method of claim 1, wherein the at least some of the plurality of basis functions are determined, by performing a dimensionality reduction, based on a set of exponential-type decay functions representing an impulse response of the gradient system.

10. The method of claim 9, wherein the at least some of the plurality of basis functions are determined by performing a singular value decomposition (SVD) or a principal component analysis (PCA) based on the set of exponential-type decay functions representing the impulse response of the gradient system.

11. The method of claim 1, wherein the plurality of exponential-type decay functions are selected from:
a plurality of exponential decay functions,
a plurality of power-law decay functions, and
a plurality of Padé-type decay functions.

12. The method of claim 5, wherein the optimizing of the numerical kernel and the plurality of weights is performed as:
a joint optimization for both the numerical kernel and the plurality of weights, or
separate optimizations for the numerical kernel and the plurality of weights, respectively.

13. The method of claim 1, wherein the input gradient includes a pulsed diffusion gradient for sensitizing the MRI system to diffusion of water molecules.

14. An apparatus for image reconstruction in a magnetic resonance imaging (MRI) system, the apparatus comprising:
processing circuitry configured to
receive k-space data acquired by scanning an imaging object using the MRI system with an input gradient applied to a gradient system of the MRI system, and
reconstruct an image of the imaging object, based on the received k-space data, the input gradient, and a gradient response model of the gradient system,
wherein the gradient response model is determined by:
measuring a gradient field generated by the gradient system in response to a probing gradient,
constructing the gradient response model of the gradient system, based on a numerical kernel and a plurality of basis functions, wherein at least some of the plurality of basis functions are each expressed as a sum of a plurality of exponential-type decay functions,
using the constructed gradient response model to predict a gradient field generated by the gradient system in response to the probing gradient, and
optimizing model parameters of the constructed gradient response model by minimizing an error between the predicted gradient field and the measured gradient field.

15. The apparatus of claim 14, wherein the measured gradient field is measured with delayed measurement start times.

16. The apparatus of claim 14, wherein the probing gradient includes a sequence of trapezoidal nominal gradients.

17. The apparatus of claim 14, wherein the minimizing of the error between the predicted gradient field and the measured gradient field includes applying a pattern mask to the predicted gradient field.

18. The apparatus of claim 14, wherein the constructed gradient response model is a sum of the numerical kernel and a weighted sum of the plurality of basis functions.

19. A magnetic resonance imaging (MRI) system, the system comprising:
first processing circuitry, configured to receive k-space data acquired by scanning an imaging object using an MRI scanner having a gradient system, with an input gradient applied to the gradient system; and
second processing circuitry, configured to reconstruct an image of the imaging object, based on the received k-space data, the input gradient, and a gradient response model of the gradient system,
wherein the gradient response model is determined by:
measuring a gradient field generated by the gradient system in response to a probing gradient,
constructing the gradient response model of the gradient system, based on a numerical kernel and a plurality of basis functions, wherein at least some of the plurality of basis functions are each expressed as a sum of a plurality of exponential-type decay functions,
using the constructed gradient response model to predict a gradient field generated by the gradient system in response to the probing gradient, and
optimizing model parameters of the constructed gradient response model by minimizing an error between the predicted gradient field and the measured gradient field.

20. The system of claim 19, wherein the MRI scanner is integrated with the system, or is located outside of the system but communicatively coupled to the system.
